(19) United States
(12) Patent Application Publication
(10) Pub. No.: US 2023/0242394 A1
(43) Pub. Date: Aug. 3, 2023

(54) COMPACT, EASY-TO-PRODUCE MEMS PACKAGE WITH IMPROVED PROTECTIVE PROPERTIES

(71) Applicant: Hahn-Schickard-Gesellschaft für angewandte Forschung e. V., Villingen-Schwenningen (DE)

(72) Inventors: Achim Bittner, Heilbronn (DE); Alfons Dehé, Reutlingen (DE)

(21) Appl. No.: 18/004,527

(22) PCT Filed: Jul. 1, 2021
(86) PCT No.: PCT/EP2021/068165

§ 371 Date: Jan. 6, 2023

(30) Foreign Application Priority Data
Jul. 7, 2020 (EP) 20184559.1
Oct. 19, 2020 (EP) 20202552.4

(51) Int. Cl. B81C 1/00; B81B 7/00

(52) U.S. Cl. CPC B81C 1/00309; B81B 7/0061; B81C 2203/0136; B81C 2203/0707; B81B 2201/0257; B81B 2201/047; B81B 2201/0214; B81B 2201/0271; B81B 2207/012; B81B 2207/015; B81B 2203/0127; B81B 2207/07

(57) ABSTRACT

Preferably, the invention relates to a MEMS package having at least one layer for protecting a MEMS element, wherein the MEMS element has at least one MEMS interaction region on a substrate and a surface conformal coating of the MEMS element is applied with a dielectric layer. Particularly preferably, the invention relates to a MEMS transducer package in which a MEMS element, for example with a MEMS membrane and processor, preferably an integrated circuit, are present on a substrate. For protection, a surface conformal coating of a dielectric is preferably first applied to the MEMS element, for example by spray coating, mist coating, and/or vapor coating. Then, preferably, an electrically conductive layer is applied. Depending on the configuration, the layers may be removed in some regions above a MEMS interaction region of the MEMS element, for example for a sound port of a MEMS membrane.

Preferably, the invention relates to a MEMS package having at least one layer for protecting a MEMS element, wherein the MEMS element has at least one MEMS interaction region on a substrate and a surface conformal coating of the MEMS element is applied with a dielectric layer. Particularly preferably, the invention relates to a MEMS transducer package in which a MEMS element, for example with a MEMS membrane and a processor, preferably an integrated circuit, are present on a substrate. For protection, a surface conformal coating of a dielectric is preferably first applied to the MEMS element, for example by spray coating, mist coating, and/or vapor coating. Then, preferably, an electrically conductive layer is applied. Depending on the configuration, the layers may be removed in regions above a MEMS interaction region of the MEMS element, for example for a sound port of a MEMS membrane.

### BACKGROUND AND PRIOR ART

Today, microsystems technology is used in many fields of application for the production of compact, mechanical-electronic devices. The microsystems (microelectromechanical systems, MEMS for short) that can be produced in this way are very compact (micrometer range) with excellent functionality and ever lower production costs.

Applications of MEMS technology include MEMS-based optical emitters or receivers, filters, electrochemical sensors, gas sensors, or even MEMS acoustic transducers.

MEMS transducers are preferably MEMS sound transducers and can be designed, for example, as MEMS microphones or as MEMS loudspeakers. Both functionalities can also be fulfilled by one MEMS transducer. Such MEMS transducers are used, for example, in modern smartphones.

MEMS transducers preferably comprise a MEMS device (e.g. MEMS chip) with a vibratable membrane, the vibrations of which are generated and/or read out, for example, by piezoelectric or piezoresistive components on or at the membrane. Likewise, capacitive methods for generating and/or measuring vibrations of the membrane are known.

The MEMS transducers are often arranged on a substrate together with an integrated circuit (IC) for controlling and/or evaluating the oscillations and are in contact with these via electrical connections, which are made, for example, by wire bonds and/or are applied in the substrate, e.g. by conductor tracks. The substrate functions in particular as a carrier and can be designed, for example, as a printed circuit board (PCB) or as a ceramic. In addition to the carrier function, it can preferably also implement electrical functions, e.g. provide electrical connections for the individual components.

An IC is preferably an electronic component by which a control unit or a regulation unit is realized. In particular, it is an electronic chip. This can, for example, have an application-specific integrated circuit (ASIC), which is particularly suitable for mass production. However, it can also be a programmable logic device (PLD), e.g. a field programmable gate array (FPGA), especially for individual applications.

MEMS elements, such as a MEMS transducer, are mostly sensitive to external influences and are therefore protected by so-called packaging.

In this respect, the packaging of MEMS elements fulfills several tasks. These include protecting the component from dust, moisture and liquids, as well as from ESD (electrostatic discharge). At the same time, however, the functional properties of the MEMS element, for example the acoustic properties of an acoustic MEMS transducer, should be preserved.

The package preferably fulfills a housing function for the MEMS element. On a bottom side of the MEMS element, a substrate itself can fulfill this function. In addition, protection is required above the substrate for the components arranged on it.

The MEMS device or the MEMS device can be arranged on the substrate conventionally or in a so-called flip-chip assembly, whereby the chip is mounted with the active contacting side facing downwards towards the substrate and without further connecting wires. For this purpose, the substrate itself preferably has contact bumps. This advantageously leads to small dimensions of the housing and short lengths of the electrical conductors.

The MEMS device and/or MEMS membrane may be present on the substrate in a MEMS acoustic transducer in a variety of ways.

The volume in which sound waves are to be measured and/or generated as seen from the MEMS membrane is preferably referred to as the front volume. The other side is preferably referred to as the back volume. This is preferably closed and has no direct connection to the front volume except possibly via an opening in the membrane. Depending on the arrangement, the back volume can be located, for example, between the membrane and the substrate. In this case, the front volume is located above the MEMS device and substrate. A housing component located here (e.g. a cover), which closes the package at the top, preferably has a sound port in this region.

However, the back volume can also be located between the membrane and the housing component arranged above the MEMS device and substrate. This is then preferably completely closed. The front volume is then preferably located between the membrane and a sound port in the substrate. Dimensions and geometry of these volumes as well as their size ratio influence the acoustic properties of the MEMS transducer. The MEMS membrane can preferably be present in both described constellations within the height of the MEMS device, either arranged at an upper end or at a lower end, towards the substrate.

In the case of a MEMS transducer, the electrical components of the MEMS device itself, e.g. electrodes of a capacitive MEMS transducer are preferably present in the back volume or arranged towards the back volume (e.g. on the side of the membrane oriented towards the back volume), for example to enable the measurement of some liquids by the membrane without short-circuiting or contaminating these components. Preferably, this allows the fluid to be in direct contact with the membrane. General protection against short circuits caused by moisture is also achieved in this way. However, a prerequisite for this is that the package prevents moisture/liquid from entering other areas of the MEMS transducer via the sound port. A sound port in the package should therefore be an opening only to the membrane, not to other areas of the MEMS transducer.

Prior art packages (see e.g. Dehe et al. 2013) for MEMS transducers have a metal cover. These covers enclose a volume that is significantly larger than theoretically needed for the underlying components of the MEMS transducer. The main reason for this is to maintain a distance between the cover and the components, some of which are electrically conductive (e.g. wire bonds, electrodes of capacitive MEMS transducers, etc.), to avoid short circuits. At the same time, metal is desirable as a starting material for these covers because it is mechanically stable and hermetically sealed, especially against water and air. Hermetically sealed refers in particular to impermeability under the transducer's usual operating conditions, i.e. preferably also at pressures that are considerably higher than atmospheric pressure. In addition, sensitive components can be electromagnetically shielded. In this way, negative influences and electrostatic discharges (ESD) can be avoided. However, these covers counteract the compact design of modern MEMS transducers.

Metal covers can be provided with an opening for sound. Even then, however, direct contacting of the MEMS membrane with a material to be measured (solid, gas, liquid) is difficult because the opening is located at some distance above the membrane (see above) and this distance would have to be overcome. In addition, because the cover and opening are not flush with the transducer components, liquid can get into the space between the cover and the MEMS devices, which can cause short circuits between their electrically conductive regions and promote the ingress of dirt and other harmful substances.

A sound port through the substrate (see also Dehé et al.) has in particular the disadvantage that due to the dimensions of the aperture and the length of the aperture, which is predetermined at least by the thickness of the substrate, a low-pass filter for sound frequencies is created, which in particular opposes the usability of an ultrasonic transducer.

So-called flip-chip packages (Feiertag et al., 2010) can reduce the height of the covers because they no longer have to be designed for wire bonds. However, the miniaturization effect is also small here.

The use of metallized polymer films as an outer packaging layer is also known from Feiertag et al. For this purpose, polymer films are laminated onto the upper side of the MEMS transducers and then provided with a metal layer. However, the process is costly. In addition, the film must be thermally deformed for this purpose and/or heated by laser ablation during post-processing/structuring, which introduces temperature into the MEMS transducer.

Heating makes thermoplastics easier to form, which is used in comparable blow molding or thermoforming of polymers. However, in all these processes, additional stress is exerted on the component. This can introduce stresses into the component or cause other damage as well as unwanted outgassing. It is also difficult to place the film flush and tightly over the MEMS transducer on all sides, so leakage from the package environment can occur and the compact design suffers.

U.S. Pat. No. 6,956,283 B1 discloses a method for protecting components of a MEMS sensor from external influences in a “package first, release later” approach. A matrix array of micromirrors is placed on a silicon chip, which in turn is placed on a substrate. In the proposed method, a protective layer is applied to the substantial components of the sensor. Various methods can be used for coating, such as spraying or vacuum coating. After deposition, the protective layer is removed over an active region. Finally, a cover is applied as a protective housing.

US 2019/0148566 A1 relates to a production method of a semiconductor sensor element, wherein it can be a pressure sensor, a gas sensor, or a capacitive sensor. The semiconductor sensor element comprises a substrate, on which a semiconductor element is located, which is connected to the substrate via bonding wires. A dielectric layer is deposited on the semiconductor sensor element via an evaporation process. Laser beams can be used to partially remove the dielectric layer. A cover is used to protect the semiconductor element from external forces.

US 2019/0311961 A1 discloses a semiconductor sensor comprising a substrate with a chip thereon. A film layer is deposited on the components of the semiconductor sensor to protect it, for example, from external gases, liquids, etc. The film layer is preferably applied via vapor deposition and over all components of the sensor that are located within the package. The housing includes an opening and is used to protect and support the components of the semiconductor sensor.

A MEMS package that can function without a rigid lid or package is not known in the prior art.

In light of the disadvantages of the prior art, there is thus a need for alternative or improved packages as well as production methods for packages for MEMS elements, in particular MEMS transducers.

### Objective of the Invention

The objective of the invention is to provide a MEMS package as well as a method for production such a MEMS package, which do not have the disadvantages of the prior art. In particular, one objective of the invention was to provide a MEMS package which is very compact, at the same time offers the MEMS element, for example a MEMS transducer, a high level of protection against dust, moisture, liquids and ESD and ensures the desired functional properties, for example acoustic properties in the case of a MEMS transducer. The package is also said to be particularly easy and cost-effective to produce and suitable for mass production due to fewer and simple steps.

### SUMMARY OF THE INVENTION

The objective is solved by the features of the independent claims. Preferred embodiments of the invention are described in the dependent claims.

The invention preferably relates to a production method for a MEMS package having at least one layer for protecting a MEMS element, comprising the following steps:
Providing a MEMS element comprising at least one MEMS interaction region on a substrate
Surface conformal coating of the MEMS element with a dielectric layer.

Preferably, the MEMS interaction region is an essential functional component of the MEMS element, which preferably interacts with a medium in a desired manner.

A surface conformal coating is, in particular, a coating that is substantially in direct and form-retaining close contact with the underlying structures.

Substantially direct and form-retaining preferably means that the majority of the coating is in direct contact, but includes volumes not filled by components in some regions, for example in corner regions or below a wire bond.

The surface conformal coating is preferably completely surface conformal. This means in particular that the coating is almost perfectly close-fitting or surface conformal and even the smallest structures can be coated in a close-fitting manner. The smallest structures are preferably structures with dimensions of the order of maximum 10 nanometers (nm), maximum 100 nm, maximum 1 micrometer (μm), maximum 10 μm or maximum 100 μm.

The dielectric layer preferably comprises at least one polymer. These are inexpensive and easy to process. It may also be preferable to apply an oxide or nitride layer as the dielectric layer. For surface conformal coating, physical or chemical vapor deposition (PVD and CVD) are particularly suitable for this purpose.

In a preferred embodiment, the polymer is a photostructurable polymer, e.g. by appropriate admixtures of photosensitive components. In particular, it is a photoresist.

Advantageously, the properties of the polymer can be adapted to the functionality of a MEMS element. In the case of a MEMS transducer as a MEMS element, for example, it may be preferable to adapt the relative permittivity εᵣ of the polymer to high-frequency applications of the MEMS transducer. For example, εᵣ can be chosen to attenuate high-frequency electro-magnetic fields.

Such a functional coating with a dielectric is not possible with prior art processes and advantageously provides an extremely compact protective layer that provides electrical insulation and mechanical protection of the MEMS element.

In a preferred embodiment, the MEMS element is selected from the group: optical MEMS transducer, acoustic MEMS transducer, MEMS sensor, in particular MEMS gas sensor and/or MEMS filter. It was recognized by the inventors that the proposed packaging can provide reliable protection for a number of different MEMS elements by means of a dielectric coating, preferably with a polymer.

On the one hand, a hermetic, space-optimized protective layer can be applied extremely cost-effectively by surface conformal coating, for example by a spray process with a polymer. On the other hand, the surface conformal coating, for example using photostructurable polymers, allows a high degree of flexibility with regard to a planned opening or recess of the protective layer in an interaction region of the MEMS element.

The MEMS interaction region preferably means a functional component of the MEMS element that interacts with an external medium in a desired manner. In the case of an acoustic MEMS transducer, for example, it is a MEMS membrane. In the case of an optical MEMS transducer, for example, it is an optical emitter.

In both cases, it is preferred that, on the one hand, no protective layer is applied directly in the interaction region of the MEMS element thereby reducing the interaction of the MEMS element with the environment (sound emission or reception, transmission or reception of optical signals), while the protection of the sensitive electronic components is ensured. The method according to the invention achieves this in a simple and highly efficient manner by means of a surface-form coating preferably by applying a polymer.

In a preferred embodiment, the MEMS element is an optical MEMS transducer, wherein the MEMS interaction region comprises an optical emitter and/or an optical receiver.

An optical emitter may include, for example, a surface emitter or VCSEL (vertical-cavity surface-emitting laser) or an LED. An optical receiver is, for example, a photodiode or an image sensor.

In a preferred embodiment, the optical emitter may be a modulable MEMS emitter. For example, modulation of the intensity of the optical emitter can be accomplished using aperture structures and MEMS actuators, such as an electrostatic actuator, a piezoelectric actuator, an electromagnetic actuator, and/or a thermal actuator.

In a preferred embodiment, the MEMS element is a MEMS acoustic transducer, wherein the MEMS interaction region comprises a MEMS membrane.

In a preferred embodiment, the MEMS transducer is a MEMS speaker, a MEMS microphone, and/or a MEMS ultrasonic transducer. Preferably, the MEMS membrane is vibratable. A membrane is preferably a thin, planar structure having a perimeter in, for example, a substantially circular and/or polygonal configuration. The membrane is preferably vibratable at least regionally along one of the perimeters.

Terms such as substantially, approximately, about, etc. preferably describe a tolerance range of less than ±20%, preferably less than ±10%, even more preferably less than ±5% and in particular less than ±1%. Indications of substantially, approximately, about, etc. always also disclose and include the exact value mentioned.

A MEMS speaker or MEMS microphone preferably refers to a speaker or microphone which is based on MEMS technology and whose sound-generating or sound-receiving structures at least partially have dimensions in the micrometer range (1 μm to 1000 μm). Preferably, the vibratable membrane may have a dimension in the range of less than 1000 μm in width, height and/or thickness.

The term MEMS transducer refers to both a MEMS microphone and a MEMS speaker. In general, the MEMS transducer refers to a transducer for interaction with a volume flow of a fluid, which is based on MEMS technology and whose structures for interaction with the volume flow or for receiving or generating pressure waves of the fluid have dimensions in the micrometer range (1 μm to 1000 μm). The fluid can be a gaseous fluid as well as a liquid fluid. The structures of the MEMS transducer, in particular the vibratable membrane, are designed to generate or receive pressure waves of the fluid.

For example, as in the case of a MEMS speaker or MEMS microphone, it may be sound pressure waves. However, the MEMS transducer may equally be suitable as an actuator or sensor for other pressure waves. Thus, the MEMS transducer is preferably a device that converts pressure waves (e.g., acoustic signals as sound pressure waves) into electrical signals or vice versa (converting electrical signals into pressure waves, such as acoustic signals).

MEMS transducers preferably comprise a MEMS device (e.g., MEMS chip) with a vibratable membrane whose vibrations are generated and/or read out, for example, by piezoelectric or piezoresistive components on or at the membrane.

In a preferred embodiment, the MEMS transducer is a piezoelectric MEMS transducer.

Similarly, capacitive methods for generating and/or measuring vibrations of the membrane are known.

In a preferred embodiment, the MEMS transducer is a capacitive MEMS transducer.

In preferred embodiments, MEMS transducers may also be MEMS ultrasonic transducers suitable for transmitting and/or receiving ultrasound.

In particular, these are capacitive micromechanical ultrasound transducers (CMUT), piezoelectric micromechanical ultrasound transducers (PMUT) or combined ultrasound transducers (piezoelectric composite ultrasound transducers, PC-MUT).

Ultrasound covers frequencies from 1 kilohertz (kHz), typically mainly from 16 kHz. Applications of compact ultrasonic transducers include imaging methods, e.g. in medicine, but also in the measurement of other objects. Applications for ultrasonic density measurement, for strength measurement of concrete, gypsum and cement, for level measurement of liquid and solid media of different consistencies and surface properties or for an ultrasonic microscope are also conceivable. Here, it is often desirable that the membrane of the transducer (i.e. of the MEMS interaction region) is in direct contact with the object/liquid to be measured.

With the method according to the invention for surface conformal coating of a dielectric protective layer, this can be advantageously achieved without impairing the protective functions. Instead, in a simple manner, the dielectric protective layer in the interaction region can be removed in a targeted manner, while the layer remains in close contact with the remaining structures. In particular with regard to acoustic MEMS transducers—such as MEMS microphones or MEMS speakers—influences on the acoustic behavior can be avoided in this way and excellent detection or sound results can be achieved.

In another preferred embodiment, the MEMS element is a MEMS gas sensor, wherein the MEMS interaction region comprises a MEMS membrane and/or a MEMS electrochemical sensing region.

For example, it may be a photoacoustic spectroscope with a MEMS sensor.

In photoacoustic spectroscopy, intensity-modulated infrared radiation is preferably used with frequencies in the absorption spectrum of a molecule to be detected in a gas. If this molecule is present in the beam path, modulated absorption takes place, leading to heating and cooling processes whose time scales reflect the modulation frequency of the radiation. The heating and cooling processes lead to expansions and contractions of the gas, causing sound waves at the modulation frequency. These can be measured by sensors such as sound detectors or flow sensors.

Preferably, the power of the sound waves is directly proportional to the concentration of the absorbing gas. Thus, a photoacoustic spectroscope preferably comprises at least one emitter, a detector, and a cell. In a MEMS gas sensor, the detector is preferably implemented as a MEMS sensor.

For example, a MEMS sensor may include a capacitive or optically readable piezoelectric, piezoresistive, and/or magnetic beam and/or a capacitive, piezoelectric, piezoresistive, and/or optical microphone or membrane.

In terms of the invention, the MEMS sensor of a photoacoustic spectroscope can preferably be understood as its MEMS interaction region, since it is preferably in direct contact with a medium.

In another preferred embodiment, the MEMS element is a MEMS filter, preferably a MEMS frequency filter, in particular a SAW or BAW filter, wherein the MEMS interaction region comprises a MEMS filter structure, in particular MEMS electrodes and/or a MEMS bulk region.

A SAW filter is preferably an acoustic surface wave filter, (likewise AOW filter), which is in particular a bandpass filter for electrical signals.

These are preferably based on interference of signals of different transit times and preferably use the piezoelectric effect. Preferably, each piezoelectric single crystal comprises a pair of comb-shaped interlocking electrodes, which preferably form the interaction region.

BAW filters (bulk acoustic wave) are preferably similar electronic filters with bandpass characteristics. However, in contrast to the SAW filter, they preferably have a substrate (bulk) in which the propagation of the acoustic waves takes place. This substrate or bulk area preferably forms the MEMS interaction region.

In a preferred embodiment of the invention, the surface conformal coating is performed by a dielectric coating process, wherein the coating process is selected from the group consisting of: spray coating, mist coating, electroplating, and/or vapor coating.

Spray coating preferably refers to a two-dimensional application of the dielectric layer, with the dielectric preferably being pressurized before spraying (e.g. higher than the prevailing ambient pressure, e.g. in the case of atmospheric pressure preferably at more than 1 bar, more preferably at more than 2 bar, in particular at 2-6 bar), so that fine particles/aerosols of the dielectric and/or a foam are formed. In this way, a particularly fine coating can be achieved which covers all sprayed areas, even if, for example, these have surfaces which are at an unfavorable angle to the spray direction. Even surfaces/regions that are angled relative to one another can thus preferably be covered directly. When using a film as in the known prior art, however, it is extremely difficult to cover such regions directly without creating uncovered volumes. This is due, for example, to the fact that the film is continuous and under tension.

Preferably, for the coating process, a liquid dielectric is atomized under increased pressure compared to the environment and applied over the surface.

Spray coating is preferably a spray paint.

The spray coating and/or surface conformal coating can also be a gas phase deposition, in particular if the dielectric layer comprises a polymer that can be deposited from the gas and/or liquid phase, e.g. tetraethyl orthosilicate (TEOS) and/or parylene. In this way, a particularly close-fitting or surface conformal coating can be achieved on the transducer components.

A mist coating preferably comprises a coating by fine droplets of the dielectric, which are finely dispersed in an atmosphere (preferably a gas). A mist coating preferably allows a fully surface conformal coating to be achieved.

A vapor coating is preferably applied by a dielectric in vapor form, or in gaseous form. A vapor coating can, for example, comprise a PVD (physical vapor deposition) or a CVD (chemical vapor deposition). Vapor deposition advantageously enables a fully surface conformal coating of a dielectric.

In a preferred embodiment, the surface conformal coating is applied by depositing a dielectric layer using a physical vapor deposition (PVD) or chemical vapor deposition (CVD) process.

In a preferred embodiment, the dielectric layer is an oxide or nitride layer, which was preferably deposited by means of a physical or a chemical vapor deposition (CVD).

An oxide or nitride layer may be, for example, a layer of a metal or semimetal oxide or a metal or semimetal nitride.

In a preferred embodiment, the dielectric layer is a layer comprising an aluminum nitride, silicon nitride, aluminum oxide, silicon dioxide, titanium dioxide, and/or tantalum oxide. An electroplated coating may also be included in the surface conformal coating. Electroplating preferably refers to the electrochemical deposition of coatings on substrates (in this case the MEMS element).

In a preferred embodiment, the surface conformal coating is provided by a coating wetting the MEMS element at least in some regions.

Wetting preferably means completely wetting or substantially completely wetting. Completely wetting preferably means that the dielectric, which is preferably applied in liquid form, spreads on the surface in the form of a flat disc. In particular, there is no macroscopic contact angle.

Preferably, it is a substantially nearly monomolecular film with a contact angle of zero.

Preferably, the spreading parameter S describes the difference between the surface tension of the substrate (GS), the surface tension of the liquid (GL) and the interfacial tension between substrate and liquid (GSL). Preferably, this can be used to distinguish between complete and partial wetting:

S=GS−GL−GSL

If S>0, the dielectric completely wets the substrate. The case S<0 characterizes partial wetting.

Preferred means completely wetting S>0.

In a preferred embodiment, the dielectric, coating method, and/or a surface of the MEMS element are configured (at least regionally) for wetting coating.

How exactly the materials, the droplet size of the dielectric, the roughness of a surface, etc. have to be selected in order to obtain a desired wetting is known to the person skilled in the art. Approaches according to Härth et al., 2012, for example, can be followed to calculate the relevant variables.

In a preferred embodiment, the surface conformal coating is performed by de-wetting the MEMS element at least in regions, the regions preferably comprising the MEMS interaction region.

Particularly preferably, the surface conformal coating is carried out by means of a coating that wets the MEMS element at least in certain regions, with a wetting coating being applied in the MEMS interaction region.

Dewetting preferably means that the dielectric contracts on the surface to form a substantially spherical drop and/or has a contact angle greater than 90°. With a slight inclination of the surface, the droplet preferably slides down without any liquid residue, in particular the liquid (the dielectric) beads off. Preferably, the dielectric has a contact angle of substantially 180° when applied to the surface and the liquid droplet contacts the solid at substantially only one point. This makes it particularly easy to remove the dielectric from the MEMS interaction region after coating.

In a preferred embodiment of the invention, the dielectric, coating method, and/or regions of the surface of the MEMS element, preferably the MEMS interaction region, are configured for a wetting coating.

Preferably, the same considerations play a role as in the case of wetting coating. With regard to the choice of the droplet size of the dielectric, the roughness of a surface, etc., the person skilled in the art can be guided by well-known approaches in the technical literature (see among others Härth et al., 2012).

In a preferred embodiment, the dielectric layer and/or dielectric comprises a polymer or polymer blend.

Polymers preferably denote a chemical compound, consisting of chain or branched molecules (macromolecule), which are made up of identical or similar units (the so-called monomers).

Non-limiting examples of polymers are polymethyl methacrylates (PMMAs), poly(methyl methacrylate-co-methacrylic acid) (PMMA co MA), poly(α-methylstyrene-co-chloromethacrylic acid methyl ester) (PMS co CI-MMA), polystyrene (PS), polyhydroxystyrene (PSOH), poly(hydroxystyrene-co-methyl methacrylate) (PSOH co MMA), phenolic resins, particularly preferably polyimides (PI) or also parylene.

Polymers are particularly suitable for dielectric coating due to their ease of processing and form-fitting coating capability.

In a preferred embodiment, the polymer for coating the MEMS element with a dielectric layer is a photostructurable polymer or a photostructurable polymer blend. Photostructurable preferably means structurable by light, electrons and/or ion radiation.

The dielectric layer can be formed particularly easily by a polymer coating, preferably by means of a photostructurable polymer or a photostructurable polymer blend. A photostructurable polymer or polymer blend preferably refers to a coating that can be modified by exposure (irradiation with electromagnetic radiation) in order to obtain a structure by subsequently dissolving out certain regions depending on the irradiation that has taken place.

A polymer blend can be kept photostructurable, for example, by appropriate admixtures of photosensitive components. Particularly preferably, a photostructurable polymer or a photostructurable polymer blend is a photoresist.

This advantageously allows the subsequent removal of a dielectric layer, for example in a MEMS interaction region, using optical methods. Region-specific removal of a dielectric layer is particularly easy if a photostructurable polymer is included in it and lithographic methods are used.

In a preferred embodiment of the invention, the surface conformal coating of the MEMS element with a dielectric layer is performed by a surface conformal coating with a photoresist.

Photoresists and photoresist compositions are well known to the person skilled in the art and are used in particular in photolithography.

Structuring a photoresist typically involves several steps, including exposing the photoresist to a selected light source through a suitable mask to record a latent image of the mask, and then developing and removing selected regions of the photoresist. In a “positive” photoresist, the exposed regions are transformed to make the areas selectively removable; while in a “negative” photoresist, the exposed regions are stabilized while the unexposed regions are removable.

A negative photoresist can preferably be polymerized by exposure and a subsequent baking step so that the region becomes insoluble to a photoresist developer. Thus, after one of the developments, only the exposed region remain. The unexposed regions, on the other hand, are dissolved by the photoresist developer.

In contrast, a positive photoresist is characterized by irradiated regions becoming soluble to a photoresist developer. The unexposed regions of the photoresist, on the other hand, remain insoluble and thus persist even after development.

Positive photoresists may comprise, for example, a polymer resin (e.g. novolak) together with a photoactive component (e.g. a polymeric diazo compound) and a solvent. Novolaks are preferably phenolic resins with a formaldehyde-phenol ratio less than 1:1, obtainable by acid condensation of methanal and phenol. After coating, preferably as a liquid, positive photoresists can be pre-baked. During this process, the solvent preferably escapes and the photoresist cures. When the photoresist is exposed to light, e.g. UV light, the resist can be structured by the photoactive component breaking the material bond in the resist at the irradiated regions. The coating becomes soluble at the exposed regions. After exposure, these regions are washed away with a suitable photoresist developer solution, leaving the unexposed parts of the photoresist. The photoresist mask can be additionally stabilized by another bake (hard-bake).

Polymer resin materials, for example, which can be activated by means of irradiation, are known as photoresists.

Polymer resin materials typically contain one or more polymers that are soluble in an aqueous base (see polymers such as PMMA or PI described above). One example of a polymer resin is Novolak.

To obtain photostructurability, photosensitive components, such as naphthoquinone diazides or a polymeric diazo compound, such as diazonaphthoquinone (DNQ), are preferably added to the photoresists.

Photoresists are processed as a solution, and suitable solvents are known to the person skilled in the art and may include, by way of example, 1-methoxy-2-propyl acetate (PMA), ethyl lactate, butyrolactone ether, glycol ethers, aromatic hydrocarbons, ketones, esters and other similar solvents.

In addition, photoresists can further comprise components such as surfactants, bases, acid formers or crosslinkers. In particular, the structuring of negative resists is based on the stabilization of exposed regions using crosslinkers. Radical initiators, such as azo-bis(isobutyronitrile) (AIBN) or dibenzoyl peroxide (DBDO), form reactive radicals by heating or irradiation (preferably short-wave light<300 nm), which causes crosslinking of the polymer matrix as a result of triggered chain reactions.

This results in a reduction of solubility in the organic photoresist developers used (e.g. MIBK developer). The exposed regions therefore remain after development. Acid formers can cross-link after activation by reaction with added aminic components (Cymel).

In preferred embodiments, a photoresist may comprise a polymer and freely selected adjuvants to impart the desired function. Examples of optional adjuvants include a photochemical acid generator, a thermal acid generator, an acid enhancer, a photochemical base generator, a thermal base generator, a photodegradable base, a surfactant, an organic solvent, a base stopper, a sensitizer, and combinations of the above adjuvants.

Such photoresists are sufficiently known in the prior art. According to the invention, however, it was recognized that they are advantageously suitable, as described, for a surface conformal coating as a dielectric protective layer for a MEMS package.

In a preferred embodiment, the dielectric layer and/or dielectric comprises a polymethyl methacrylate, a polyimide (PI), novolak, polymethyl glutarimide, polymers depositable from the gas and/or liquid phase, in particular tetraethyl orthosilicate (TEOS) and/or parylene and/or epoxy resin, in particular SU-8.

The use of polymers to provide the dielectric protective layer by means of a coating process advantageously enables a coating that is particularly conformal to the surface and allows all components to be coated in a form-fit manner. For example, spray deposition or vapor phase deposition can be used here.

Advantageously, even the smallest structures of the MEMS element can be reliably hermetically covered. Additional protection of e.g. bonding wires in case of a conventional chip design can be omitted. No further processes for underfilling flip-chip components are required either.

In addition, a polymer coating can be used to tailor the functionality of the dielectric layer to the MEMS element.

For example, it may be preferred to adapt the relative permittivity εᵣ of the polymer to high-frequency applications of a MEMS transducer. Here, εᵣ can preferably be selected such that high-frequency electro-magnetic fields are reliably attenuated.

It may also be preferred to deposit different polymers on top of each other, for example, to create a gradient in permittivity for high-frequency components, or to optimize the dielectric layer with respect to optical properties, especially if the MEMS device comprises or is comprised of a microoptoelectromechanical (MOEMS) component.

By means of a surface conformal coating process, in particular using polymers, a highly functional and extremely compact MEMS package can be easily provided, which at the same time offers full protection of the sensitive structures of MEMS elements, e.g. MEMS transducers.

In a preferred embodiment, the production method additionally comprises the following step:
Applying an electrically conductive layer to the dielectric layer at least in some regions.

The application of an electrically conductive layer to the dielectric layer, at least in certain regions, has the advantage that the resulting layer system is substantially close-fitting and protects the MEMS transducer from short circuits and electrostatic discharges and seals it against liquids and/or air. Mechanical protection is also preferably improved.

In particular, the electrically conductive layer is a metal, which provides mechanical protection to the MEMS element and protects against the penetration of air, moisture, liquids, dust into the interior of the package. In particular, a metal coating is hermetic.

By applying an electrically conductive layer—preferably a metal layer—over the dielectric layer, it is also possible to ensure a mechanically stable closure which can resist not only the penetration of air, moisture and liquids but also external forces. A layer system consisting of a metal layer on a dielectric layer thus has a particularly effective housing function, such that separate covers or housings can be dispensed with. Advantageously, the layer system also ensures a good acoustic seal and, in the case of use with a MEMS speaker or MEMS microphone, leads to very good detection or sound results.

In a preferred embodiment, the electrically conductive layer comprises a metal, preferably aluminum and/or a noble metal, preferably gold, platinum, iridium, palladium, osmium, silver, rhodium and/or ruthenium.

The electrically conductive layer is preferably applied or deposited. The electrically conductive layer is preferably a metallic layer, particularly preferably a metallic film, especially a metallic thin film.

In a preferred embodiment, the electrically conductive layer is applied by a coating process, in particular by a PVD, CVD and/or a sputtering process.

Preferably, the dielectric layer overlaps at the outer edges of the dielectric layer. Such outer edges are located, for example, on the upper side of the substrate where the dielectric layer ends. There, the electrically conductive layer preferably covers the edge area on all sides and extends onto the substrate. Such an overlap can improve the impermeability of the package.

The layer system produced in this way is extremely compact and simple to produce, but provides full protection of the MEMS element, for example a MEMS transducer. A surface conformal coating, e.g. a spray coating, can be used to achieve a close-fitting coating on all sides, which contributes to compactness and impermeability to the package environment.

Such a close fit cannot be achieved by a film. Furthermore, in contrast to the film, no additional and costly steps are necessary, which may also affect the MEMS element.

Advantageously, an electrically conductive layer can be applied directly to the dielectric layer. The layer system can be clearly distinguished visually from film packages, for example by the fineness of the layer (measurable roughness) and the direct contact with the components underneath. Also, in contrast to film-based packages, the spray coating also allows wire bonds to be covered, since the spray layer advantageously simply covers the wire bond(s) without exerting any significant force on the wire bond that could destroy it.

In a preferred embodiment, the MEMS element comprises a MEMS device and a processor, preferably an integrated circuit on the substrate, and/or an electrical connection between the MEMS device and the processor, preferably the integrated circuit. Here, it is particularly preferred that the dielectric layer as well as optionally the electrically conductive layer (preferably a metal layer) extend over the MEMS element and the processor and/or an electrical connection between the MEMS device and the processor. The layer system can thus preferably simultaneously achieve complete protection of both the sensitive micromechanical components and the electronic components or the processor. A separate housing that encloses and protects the processor and MEMS device is not necessary.

For the purposes of the invention, the term processor preferably refers to a logic circuit that can transmit, receive, and process data or electrical signals. Preferred processors include, without limitation, an integrated circuit (IC), an application specific integrated circuit (ASIC), a field programmable gate array (FPGA), a microprocessor, a microcomputer, a programmable logic controller, and/or other electronic, preferably programmable, circuitry.

For example, the substrate may be selected from a group comprising silicon, monocrystalline silicon, polysilicon, silicon dioxide, silicon carbide, silicon germanium, silicon nitride, nitride, germanium, carbon, gallium arsenide, gallium nitride, and/or indium phosphide.

In a preferred embodiment, the MEMS element and/or processor are mounted in a flip-chip design and preferably the electrical connection is made through the substrate, in particular through conductive traces in the substrate.

The surface conformal coating can preferably be applied in such a way that it encloses the MEMS element between itself and the substrate at least in certain regions and the MEMS element is thus preferably electrically insulated and/or chemically protected with the dielectric coating, but preferably at the same time the gap between the MEMS element (below the MEMS element) and the substrate is not filled with a dielectric having a high εᵣ. This can be particularly advantageous for high frequency applications.

In a preferred embodiment of the invention, the MEMS element and/or processor, preferably integrated circuit, are not mounted in a flip-chip design and preferably the electrical connection is made via at least one wire bond.

Also, unlike film-based packages, the surface conformal coating, such as a spray coating with a polymer, also allows wire bonds to be covered because the coating advantageously lays directly over the wire bond(s) without exerting any significant force on the wire bond that could destroy it.

Tensioned films, on the other hand, often destroy wire bonds, such that this type of package can generally only be used for flip-chip packages. The package created by the process described here, on the other hand, is form-fitted to the packaged structures without placing them under significant tension. This is another way in which the packages described herein can be distinguished from other packages when wire bonds are used. Wire bonds, for example, are still visible from the outside, although they are enclosed and protected by the layer system. In general, with these packages, the structure of the MEMS element is also visible from the outside through the package layer.

In a preferred embodiment of the invention, the production method comprises the following steps:
Providing the MEMS element comprising a MEMS interaction region on the substrate
Surface conformal coating, in particular spray coating of MEMS element, such that the MEMS element is completely enclosed between dielectric layer and substrate
Preferably applying an electrically conductive layer at least in some regions on the dielectric layer, which preferably forms a layer system with the dielectric layer.
Optionally, arranging an opening above the interaction region by removing the dielectric layer and/or the layer system above the interaction region at least in some regions.

In a preferred embodiment of the invention, the arrangement of the dielectric layer, the layer system of the MEMS element and/or the MEMS interaction region is such that, after removal of the dielectric layer or layer system, no electrically conductive regions are in direct contact with a package environment. In particular, these are sealed against air and/or liquid.

By removing the dielectric layer and/or the layer system comprising dielectric layer and electrically conductive layer in certain regions, the interaction of the interaction region with the desired medium, in particular with the package environment, can be improved.

For example, in the case of an acoustic MEMS transducer, the MEMS interaction region is a MEMS membrane that interacts with the package environment to pick up or generate sound pressure waves.

In the case of an optical MEMS transducer, the MEMS interaction region may be, for example, an optical emitter or receiver that interacts with the package environment by emitting or receiving electromagnetic radiation.

In both cases, it is preferred that, firstly, directly in the interaction region of the MEMS element, no dielectric layer or electrically conductive layer reduces the interaction of the MEMS element with the environment (sound emission, optical signals).

By removing the layer system and/or the dielectric layer in some regions, for example using photostructurable polymers, unhindered interaction of the MEMS element in its functional region can be achieved, while the protection of the entire electronic system can be reliably ensured.

The MEMS element preferably comprises a MEMS device having a MEMS membrane for a MEMS transducer. A MEMS package produced in this way may preferably also be referred to as a MEMS transducer package. A preferred MEMS transducer is an acoustic MEMS transducer, in particular a PMUT, CMUT and/or a PC-MUT.

Preferably, the layer system is a surface conformal layer system with respect to coated components of the MEMS element (e.g.: MEMS device, integrated circuit, and preferably electrical interconnect (especially wire bond)).

The spray coating is preferably carried out in such a way that the MEMS element is completely enclosed between the dielectric layer and the substrate. In particular, no electrically conductive and/or electrically functional regions of the MEMS element should be exposed to a package environment, so that short circuits in particular are avoided. All electrical or electrically conductive components shall preferably be covered.

In particular, the processor, preferably the integrated circuit (IC), exposed electrical wires, and electrically functional or conductive regions of the MEMS element should be covered. Such a dielectric layer advantageously provides a base for the subsequent electrically conductive layer. The dielectric layer prevents the electrically conductive layer from causing short circuits on the MEMS element. In turn, the electrically conductive layer itself provides electrical shielding of the MEMS element. Furthermore, the electrically conductive layer, if formed by a metal, for example, can provide additional mechanical protection and prevent air, moisture, liquids, dust from entering the interior of the package.

The layer system thus represents a particularly reliable barrier which, in addition to mechanical protection, prevents permeation of potentially damaging external influences such as water vapors, dust, etc.

The electrically conductive layer is preferably applied to the dielectric layer at least in certain regions. Preferably, the electrically conductive layer completely covers the dielectric layer. However, the electrically conductive layer can already be pre-structured during application in such a way that a region in which a sound port is to be created later is already recessed. Then only the dielectric layer has to be removed later. Removal of the dielectric layer is particularly easy if it comprises a photostructurable polymer and lithographic processes are used.

For example, the electrically conductive layer (e.g. metallic layer) could be pre-structured with a shadow mask and preferably use it as a hard mask for subsequent lithography (e.g. to create the sound aperture).

The application of an electrically conductive layer at least in some regions on top of the dielectric layer advantageously means that the resulting layer system is substantially close-fitting and protects the MEMS element from short circuits and electrostatic discharges and seals it against liquids and/or air. Substantially close-fitting preferably means that the majority of the coating is in direct contact, but includes volumes not filled by components in some regions, such as in corner regions or below a wire bond. If the spray coating is a vapor phase deposition, at least the dielectric layer, preferably both layers, is perfectly close-fitting or surface conformal.

Advantageously, the spray/or vapor phase deposition enables a form-fit coating of the components. No further processes for underfilling flip-chip components and no additional protection of e.g. bonding wires may be required.

In a preferred embodiment of the invention, the removal of the layer system or dielectric layer is carried out by lithographic processes, in particular by pre-structuring the dielectric layer by appropriate exposure of the photostructurable polymer.

Preferably, photolithography, electron beam lithography and/or ion beam lithography can be performed.

Preferably, such removal is carried out layer by layer. For the dielectric layer in particular, this process can be simplified if a photostructurable polymer is included.

An etching process can be performed, for example, by dry etching or wet chemical etching.

Such a process is particularly easy, fast and cost-effective to implement.

In a further preferred embodiment of the invention, the removal of the layer system is carried out by a lift-off process, wherein in particular a pre-structuring of the dielectric layer is carried out by appropriate exposure of the photostructurable polymer. In particular, the lift-off method is used to remove the entire layer system in the region of the sound port. It is possible, for example, to pre-structure the layers in such a way that both metal and polymer layers can be removed in one lift-off step, e.g. if the lift-off coating layer (in particular the dielectric layer) is thick enough or thicker than in other regions at the location to be removed.

In a preferred embodiment, the thickness of the dielectric layer is between 10 nm and 1 mm. Intermediate ranges from the aforementioned ranges may also be preferred, such as 10 nm to 100 nm, 100 nm to 200 nm, 200 nm to 500 nm, 500 nm to 1 μm, 1 μm to 5 μm, 5 μm to 10 μm, 10 μm 50 μm, 50 μm to 100 μm, 100 μm to 500 μm, or even 500 μm to 1 mm. A skilled person will recognize that the aforementioned range limits can also be combined to obtain other preferred ranges, such as 100 nm to 1 μm, 500 nm to 5 μm, or 200 nm to 10 μm.

In a preferred embodiment, the thickness of the electrically conductive layer is between 10 nm and 20 μm. Intermediate ranges from the aforementioned ranges may also be preferred, such as 10 nm to 100 nm, 100 nm to 200 nm, 200 nm to 500 nm, 500 nm to 1 μm, 1 μm to 5 μm, 5 μm to 10 μm, or even 10 μm to 20 μm. A person skilled in the art will recognize that the aforementioned range limits can also be combined to obtain other preferred ranges, such as 200 nm to 1 μm, 100 nm to 5 μm, or 500 nm to 10 μm.

The preferred thicknesses for the dielectric as well as electrically conductive layer result in excellent protection of the MEMS element, while maintaining compact design and high functionality.

In a preferred embodiment, the invention relates to a production method for a MEMS transducer package having a layer system for protecting the MEMS transducer, comprising the following steps:
Providing a MEMS device comprising a MEMS membrane on a substrate
Providing an integrated circuit on the substrate that has an electrical connection to the MEMS device
Spray coating of MEMS device, integrated circuit, and preferably electrical interconnect with dielectric layer such that MEMS device, integrated circuit, and electrical interconnect are fully encapsulated between dielectric layer and substrate
Applying an electrically conductive layer to the dielectric layer at least in some regions.

MEMS device with MEMS membrane as well as integrated circuit on the substrate including electrical connection preferably comprise the MEMS transducer. In particular, the MEMS transducer is a PMUT, a CMUT or a PC-MUT. Preferably, the electrical connection is at least one wire bond.

The preferred embodiments and described advantages for the MEMS package are equally and particularly applicable to the preferred MEMS transducer package.

The produced layer system comprising a dielectric layer and an electrically conductive layer is extremely compact and easy to produce, providing full protection of the MEMS transducer.

Particularly advantageously, the acoustic properties of the MEMS transducer are not reduced in the process.

In a preferred embodiment of the invention, a back volume of the MEMS transducer is present disposed between the substrate and the MEMS membrane, and the following step is included:
Arrangement of a sound port above the membrane by removing the layer or layer system above the membrane at least in certain regions.

The removal can be implemented, for example, by an etching process by physical processing of the layer(s).

If the electrically conductive layer was already initially not applied in this area, only the dielectric layer must be removed. Otherwise, both dielectric and electrically conductive layer must be removed. In particular, this is done in such a way that the membrane is not covered afterwards, at least in some regions, in order to maintain the acoustic properties of the MEMS transducer, or that there is direct contact between the membrane and the sound medium, at least in some regions. Since the layer system lies directly flush on the MEMS transducer, direct contact between the membrane and the sound medium can be established without the sound medium being able to reach other areas of the MEMS transducer. Thus, comprehensive protection from moisture and liquid can be achieved while maintaining acoustic properties. Flush sealing of the sound port and membrane also improves the acoustic properties of the MEMS transducer.

It is particularly preferred that this step is carried out between the spray coating and the application of the electrically conductive layer. The spray coating can then be removed by a lithography process, for example. If the electrically conductive layer, in particular the metallic layer, is not applied until after the dielectric layer has been removed, it can be ensured that the electrically conductive layer seals the edge regions of the sound aperture flush with the MEMS device, which means that the package can be guaranteed to be impermeable at this point, in particular with respect to gas (in particular air), moisture and/or liquids.

In particular, a CMUT preferably comprises two MEMS membranes. In this embodiment with sound port in the layer system, it may advantageously suffice if the lower membrane is hermetic to the package environment.

In a preferred embodiment of the invention, the arrangement of the dielectric layer, the layer system, the MEMS device and/or the MEMS membrane is such that no electrically conductive regions are in direct contact with a package environment after removal of the layer or layer system. In particular, these are sealed against air and/or liquid.

In a further preferred embodiment of the invention, electrodes of the capacitive MEMS transducer, in particular of the capacitive micromechanical ultrasonic transducer, are present arranged in or facing the back volume. For example, they are located in the back volume or on the side of the membrane facing the back volume. In this way, short circuits caused by moisture and liquids or contamination can be avoided.

In a preferred embodiment, a MEMS interaction region may be placed in a mobile state only after the dielectric layer or layer system has been deposited or removed, preferably by a release process, in particular by removing a sacrificial layer.

In particular, this ensures that the steps of the packaging method do not have a negative impact on the functionality of the mechanically sensitive and finely structured MEMS interaction regions. Instead, a preferred release process of the MEMS interaction region takes place as one of the last process steps, only after the application of the dielectric layer or the layer system and, if necessary, a targeted removal in the MEMS interaction region.

An example of a mechanically sensitive and fine-structured MEMS interaction region is a MEMS membrane in the case of a MEMS transducer as a MEMS element.

In a preferred embodiment, the MEMS membrane is brought to a vibrational state only after the layer or layer system has been applied or removed, preferably by a release process, in particular by removing a sacrificial layer.

The MEMS membrane is a crucial component of a MEMS transducer. At the same time, such a membrane is particularly finely structured and sensitive in order to achieve the desired acoustic properties. Therefore, the application of the layer system or the process of removing the layer or layer system for the sound port can affect or even destroy the membrane.

For this reason, the membrane is preferably only brought into a vibratory state afterwards, in particular by removing an appropriately structured sacrificial layer intended for this purpose, which is present, for example, between the membrane and the other transducer components and thus blocks and protects the membrane. This can be done, for example, by an etching process, preferably removing the excess material of the sacrificial layer from the package. Preferably, the sacrificial layer can be located opposite the membrane towards the front volume. Then the removal of the material via the sound port is possible. If the sacrificial layer is present in the back volume, the material is preferably removed through suitable small channels or openings. These can preferably be closed afterwards.

Such a release is particularly relevant for CMUTs, PMUTs and PC-MUTs. The advantages transfer equally to other MEMS elements.

In another aspect, the invention relates to a MEMS package producible or produced by the described production method.

In particular, the invention relates to a MEMS package comprising
a substrate
a MEMS element disposed on the substrate comprising a MEMS interaction region
a dielectric layer for protecting the MEMS element, produced by a surface conformal coating of the MEMS element by a dielectric coating process.

The person skilled in the art recognizes that technical features, definitions and advantages of preferred embodiments of the described production method fora MEMS package, apply equally to the obtained MEMS package and vice versa.

Particularly preferred, as explained. is an application of the packaging method of the invention to a MEMS transducer.

In a preferred embodiment, the invention therefore also relates to a MEMS package, which is a MEMS transducer package comprising.
a substrate
a MEMS device arranged on the substrate comprising a MEMS membrane, wherein a back volume of the MEMS transducer is preferably arranged between substrate and MEMS membrane
a processor, preferably an integrated circuit, arranged on the substrate, which has an electrical connection to the MEMS device
A layer system for protecting the MEMS transducer, produced by the following steps:
   a. surface conformal coating, preferably spray coating of MEMS device, processor and preferably electrical interconnect with a dielectric layer, in particular of a photostructurable polymer, such that MEMS device, processor, preferably an integrated circuit, and electrical interconnect are completely encompassed between dielectric layer and substrate
   b. application of an electrically conductive layer at least in regions on the dielectric layer
   c. optional arrangement of a sound port above the MEMS membrane by removing the dielectric layer or layer system above the membrane in some regions, in particular by a lithography and/or lift-off process.

Preferably, the arrangement of the layer system, the MEMS device and/or the MEMS membrane may be such that, after removal of the dielectric layer or layer system, no electrically conductive regions are in direct contact with a package environment and/or a back volume and electrically conductive regions of the MEMS transducer are sealed from air and/or liquids, wherein the back volume of the MEMS transducer is preferably arranged between the substrate and the MEMS membrane and the MEMS transducer package has a sound port above the membrane.

### DETAILED DESCRIPTION

The invention will be explained below with reference to further figures and examples. The examples and figures serve to illustrate preferred embodiments of the invention without limiting them.

FIGS. 1 to 4 illustrate a preferred embodiment of the production method for a MEMS package, using a MEMS transducer package 14 as an example.

FIG. 1 shows a MEMS transducer 1 without a finished package 14. MEMS device 2 (also referred to as MEMS device) with MEMS membrane 3 are present on a substrate 4. Likewise, an IC 5 (here in the form of an ASIC) is arranged on the substrate 4. MEMS device 2 and IC 5 are electrically connected here via a wire bond 6.

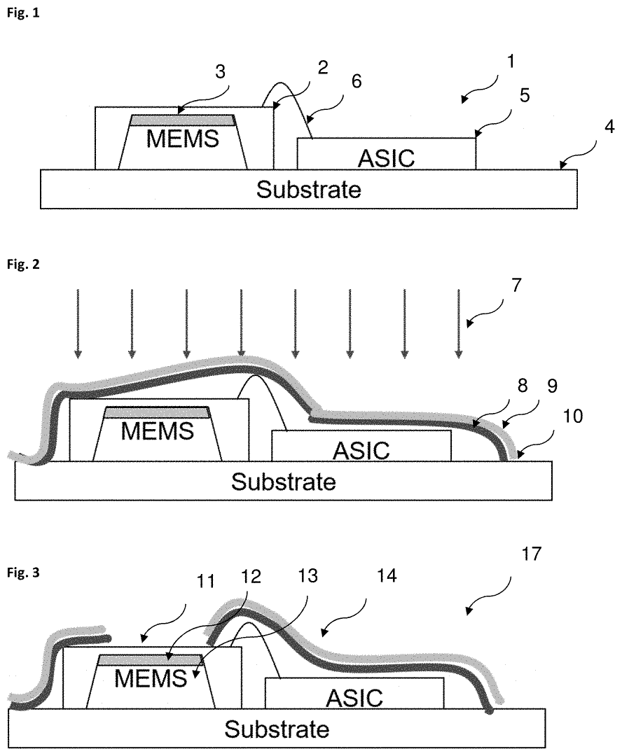

FIG. 2 schematically illustrates the application of the coating system 16 to protect the MEMS transducer 1. First, a surface conformal coating (e.g. spray coating) 7 is applied with a dielectric, which coats all components present on the substrate with a dielectric layer 8. Thus, this layer encloses these components, i.e. here MEMS device 2, IC 5 and wire bond 6 between itself and substrate 4 and is substantially close-fitting. Next, an electrically conductive layer 9 is applied to the dielectric layer 8, which also covers the outer edge regions of the dielectric layer 8 and is preferably flush with the substrate 4 at the outer edge of the coating in order to obtain a good seal there.

FIG. 3 shows a MEMS transducer package 14, which separates the MEMS transducer 1 from the package environment 17 and thus protects it. The MEMS device 2 is arranged such that the back volume 13 is located between the membrane 3 and the substrate 4. Therefore, a sound port 11 is introduced into the layer system 16 above the membrane, in which both layers 8, 9 are removed above the membrane 3, for example by a lithography process. The membrane 3 is present here as a non-released membrane, which is protected for the time being by a sacrificial layer 12.

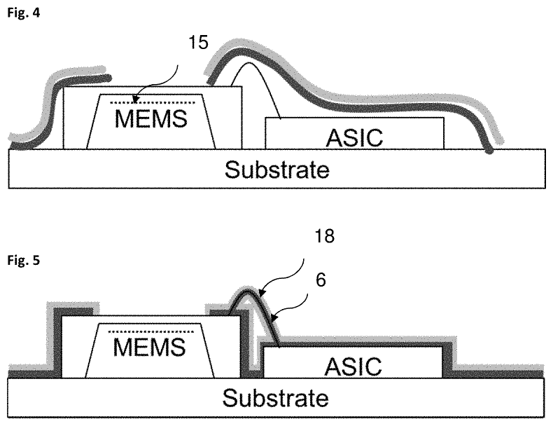

In FIG. 4, a released membrane 15 was produced by removing the sacrificial layer 12.

FIG. 5 shows a package which is preferably fully surface conformal, in which a fully surface conformal coating system 18 is produced by means of vapor phase deposition of a polymer (e.g. Parylene). It shows how close-fitting a layer system produced in this way is, in which even the structure of the wire bond 6 is retained after coating in the package 14.

### LIST OF REFERENCE SIGNS

1 MEMS element, for example MEMS transducer
2 MEMS device
3 MEMS interaction region, for example MEMS membrane.
4 Substrate
5 Processor, preferably integrated circuit (IC)
6 Electrical connection, preferably wire bond
7 Surface conformal coating (e.g. spray coating)
8 Dielectric layer
9 Electrically conductive layer
10 Outer edge of the coating
11 Opening in front of the MEMS interaction region, preferably sound port
12 Sacrificial layer of the non-released interaction region, for example, of a non-exposed
membrane
13 Back volume
14 MEMS package, for example MEMS transducer package
15 Released MEMS interaction region, for example, released MEMS membrane
16 Layer system
17 Package environment
18 Surface conformal layer system

### LITERATURE

Alfons Dehé, Martin Wurzer, Marc Fuldner and Ulrich Krumbein, The Infineon Silicon MEMS Microphone, AMA Conferences 2013—SENSOR 2013, OPTO 2013, IRS 2 2013.
Gregor Feiertag, Wolfgang Pahl, Matthias Winter, Anton Leidl, Stefan Seitz, Christian Siegel, Andreas Beer, Flip chip MEMS microphone package with large acoustic reference volume, Proc. Eurosensors XXIV, Sep. 5-8, 2010, Linz, Austria.
M. Härth, D. W. Schubert, Simple Approach for Spreading Dynamics of Polymeric Fluids. In: Macromol. Chem. Phys. 213, no. 6, March 2012, pp. 654-665.

1. A method of producing a MEMS package having at least one layer for protecting a MEMS device, comprising:
obtaining an MEMS device comprising at least one MEMS interaction region on a substrate, wherein the MEMS element comprises a MEMS device and a processor on the substrate and an electrical connection is present between the MEMS device and the processor,
coating of the MEMS device with a surface conformal coating of a dielectric layer, and
applying an electrically conductive layer at least in regions on the dielectric layer, wherein the dielectric layer and the electrically conductive layer extend over the MEMS device and the processor.

2. The method according to claim 1, wherein the MEMS element is selected from the group consisting of: an acoustic MEMS transducer, an optical MEMS transducer, an MEMS sensor an MEMS filter.

3. The method according to claim 1, wherein the surface conformal coating is implemented by a coating process with a dielectric selected from the group consisting of: spray coating, mist coating, vapor coating and/or electroplating.

4. The method according to claim 1, wherein the surface conformal coating is implemented by a coating wetting the MEMS element at least in regions where a wetting coating is implemented in the MEMS interaction region.

5. The method according to claim 1, wherein the dielectric layer and/or the dielectric comprises a polymer.

6. The method according to claim 1, wherein the electrically conductive layer comprises metal and/or the electrically conductive layer (9) is applied by a coating process.

7. The method according to claim 1, wherein the MEMS device and/or processor are mounted in a flip-chip design.

8. The method according to claim 1, for a MEMS package comprising the MEMS device and the processor comprising the following steps:
obtaining the MEMS device comprising a MEMS interaction region on the substrate
providing the processor on the substrate, which has an electrical connection with the MEMS device,
Surface conformal coating by spray coating of the MEMS device, processor and optionally the electrical connection (6) with the dielectric coating, such that the MEMS device, the processor and the electrical connection is completely enclosed between dielectric layer and substrate,
applying an electrically conductive layer at least in regions onto the dielectric layer, which forms a layer system with the dielectric layer, and
optionally arranging an opening above the MEMS interaction regions by removing the dielectric layer and/or the layer system at least in some regions above the MEMS interaction region.

9. The method according to claim 1, wherein a removal of the dielectric layer is performed by a lithographic process or a lift-off, wherein preferably the dielectric layer is formed by a photostructurable polymer and a pre-structuring of the dielectric layer is performed by corresponding exposure of the photostructurable polymer to light.

10. The method according to claim 1, wherein the layer thickness of the dielectric layer is between 10 nm and 1 mm and/or the layer thickness of an electrically conductive layer is between 10 nm and 20 μm.

11. The method according to claim 1, wherein the MEMS element is an optical MEMS transducer, and the MEMS interaction region comprises an optical emitter and/or an optical receiver, the MEMS element is an acoustic MEMS transducer and the MEMS interaction region comprises a MEMS membrane, the MEMS element is a MEMS gas sensor and the MEMS interaction region comprises a MEMS membrane and or an electro-chemical MEMS sensor region or the MEMS element is a MEMS filter, and wherein the MEMS interaction region comprises a MEMS filter structure comprising MEMS electrodes and/or a MEMS bulk region.

12. The method according to claim 1, wherein the MEMS element is a MEMS acoustic transducer and comprises a MEMS device and a processor, and the production method comprises the following steps:
obtaining the MEMS device comprising a MEMS membrane on a substrate,
providing the processor on the substrate, which has an electrical connection to the MEMS device,
Surface conformal coating by spray coating, of the MEMS device, the processor and optionally an electrical connection with the dielectric layer, such that the MEMS device, the processor and the electrical connection are completely enclosed between the dielectric layer and the substrate,
optionally applying an electrically conductive layer at least in some regions on the dielectric layer, which forms a layer system with the dielectric layer, and
optionally arrangement of a sound port above the MEMS membrane by removing the dielectric layer or layer system at least in some regions above the membrane.

13. MEMS package manufacturable by a production method according to one or more of the preceding claims.

14. MEMS package (14), comprising
a substrate,
an MEMS element arranged on the substrate comprising a MEMS interaction region, wherein the MEMS element comprises a MEMS device and a processor on the substrate,
a dielectric layer for protecting the MEMS element, produced by surface conformal coating of the MEMS element by a dielectric coating process,
an electrically conductive layer at least in regions on the dielectric layer, wherein the dielectric layer and the electrically conductive layer extend over the MEMS device and the processor.

15. The method according to claim 2, wherein the MEMS sensor is an MEMS gas sensor.

16. The method according to claim 5, wherein the polymer is selected from the group consisting of: a photostructurable polymer, a polymethyl methacrylate, a polyimide, novolak, polymethyl glutarimide, a polymer depositable from a gas and/or a liquid phase, parylene and an epoxy resin.

17. The method according to claim 16, wherein the polymer depositable from a gas and/or a liquid phase is tetraethyl orthosilicate (TEOS).

18. The method according to claim 16, wherein the epoxy resin is SU-8.

19. The method according to claim 6, wherein the metal is aluminum and/or a noble metal.

20. The method according to claim 19, wherein the noble metal is gold, platinum, iridium, palladium, osmium, silver, rhodium and/or ruthenium.

21. The method according to claim 6, wherein the coating process is a PVD, CVD and/or sputtering process.

22. The method of claim 7, wherein the electrical connection is made via the substrate.

23. The method according to claim 1 wherein the MEMS device and/or processor are present in a conventional design and not in a flip-chip design.

24. The method of claim 23, wherein the electrical connection is made via at least one wire bond.

25. The method according to claim 8, wherein the MEMS package comprises a layer system for protecting the MEMS element.

26. The method according to claim 11, wherein the MEMS filter is a MEMS frequency filter.

27. The method according to claim 26, wherein the MEMS frequency filter is a SAW or a BAW filter.
